(19) United States
(12) Patent Application Publication
(10) Pub. No.: US 2007/0105395 A1
(43) Pub. Date: May 10, 2007

(54) LASER FUNCTIONALIZATION AND PATTERNING OF THICK-FILM INKS

(76) Inventors: Edward Kinzel, Bremen, OH (US); Xianfan Xu, West Lafayette, IN (US)

Correspondence Address: BOSE MCKINNEY & EVANS LLP;JAMES COLES, 135 N PENNSYLVANIA ST, SUITE 2700, INDIANAPOLIS, IN, 46204, US

(21) Appl. No.: 11/555,861

(22) Filed: Nov. 2, 2006

Related U.S. Application Data
(60) Provisional application No. 60/733,825, filed on Nov. 4, 2005.

(51) Int. Cl. H01L 21/31; H01L 21/469

(52) U.S. Cl. 438/758

(57) ABSTRACT

An apparatus and method for producing electronic components using thick-film inks, and the electronic components manufactured therefrom. The thick-film inks, which include silver and copper inks are applied to a substrate and sintered with a laser. This process allows the fabrication of components on low temperature substrates.

### CROSS-REFERENCE TO RELATED APPLICATION

This application claims benefit to U.S. Provisional Patent Application Ser. No. 60/733,825 titled LASER FUNCTIONALIZATION AND PATTERNING OF THICK-FILM INKS to Edward C. Kinzel and Xianfan Xu filed Nov. 4, 2005, the disclosure of which is expressly incorporated by reference herein.

### FIELD OF THE INVENTION

The present invention relates to a laser based method for producing electronic components using thick-film inks, and the electronic components manufactured therefrom. More particularly, the present invention relates to a method for producing electronic components using copper thick-film inks in an ambient (air) environment. The present invention is also applicable to sintering many different types of materials, including refractory metals, dielectrics, and semiconductors.

### BACKGROUND OF THE INVENTION

Electronic manufacturers currently fabricate a large variety and wide range of passive electronic components such as resistors, capacitors, and inductors for use in micro electronic devices. In addition to these passive components, a micro electronic device also includes a large number of interconnects or interconnecting conductors to connect passive and active components into a functioning circuit. In some cases, high quality surface mount passive devices are soldered to a printed circuit board. In other instances, such circuits can be reduced in size to integrate the devices into hybrid microcircuits.

In one instance, a Low Temperature Co-fired Ceramic (LTCC) process provides for the integration of more than one distinct fabrication technology. For instance, semiconductor die and integrated passives define the hybrid micro circuit. The LTCC process has several limitations, however, including a high processing temperature (850° C.), certain restrictions based on tolerance and morphology, as well as a complex fabrication cycle. The high processing temperature prevents the use of the technology with certain substrates including flexible/conformal polymer substrates. In addition, it is difficult for this patterning technology to produce products with feature sizes less than 75 micrometers.

Thin-film technologies also exist which include the vacuum evaporation of materials which are used in the fabrication of integrated circuits. Such techniques can produce film thicknesses between three nanometers and 2,500 nanometers. However, such techniques are generally too expensive to manufacture most meso-scale devices. There are also limitations in the materials that can be deposited on the substrate.

Thick film devices exist which are created by depositing patterns onto a substrate and then bulk processing the deposited material for functionalization. The most common patterning technique is screen printing. This screen printing process is an additive process and has the advantage of minimizing waste material/or material waste. However, the entire component must be fired at 850° C. to functionalize the device.

For a thick-film fabrication, the ink is patterned when it is still wet. In this form, the film is not functional. Conventional thick-film technology or screen printing involves forcing a viscous paste through apertures in a screen. This technique produces patterns with thicknesses greater than 2.5 micrometers and up to 50 micrometers. Patterns are generated by sealing apertures in the screen except where the ink is required to pass through for the creation of the pattern. After the ink is patterned onto the substrate, it is dried and fired in a furnace. The firing temperature for most inks is 850° C. Consequently, this high firing temperature restricts the acceptable substrates to ceramics such as alumina.

After patterning, organic material in the ink must be driven off and the conductive/dielectric/resistive particles must be fused together by sintering. In both of these processes, the removal of organic material and the sintering are accomplished by applying heat to the device. As mentioned previously, the functionalization temperature for most thick-film inks is 850° C. which is well in excess of the melting point or destruction point for polymers and most glass-based substrates.

The high firing temperatures required to functionalize the ink and bond it to the substrate limit the use of copper conductors. In conventional thick-film processing copper conductors can only be fired in a nitrogen atmosphere to prevent oxidation. However, oxygen is necessary for the burnout of the organic components in resistive and dielectric conventional inks making them incompatible with the nitrogen atmosphere required for firing copper conductors. Specially designed resistive and dielectric inks for this process are available, however, the additional complexity and expense has prevented the acceptance of copper based conductors despite their performance and lower material cost.

A conventional thick-film sintering process often takes place in a belt-fed furnace. After a pattern has been deposited on the substrate, the ink must be dried. This drying process allows the volatile organic solvents to evaporate. Evaporation often first takes place in the air while the pattern is allowed to settle. The drying process then continues inside a drying portion of an oven at 120 to 150° C. If solvents are not removed prior to exposing the solvent/substrate combination to higher temperatures, solvents can become trapped below the surface of the solvent where expansion can cause blistering or other damaging effects. After the volatile organic solvents have been driven off, the substrate is slowly heated to 500° C. After completion of the burn out stage, the ink is heated to 700° C. This allows the glass frit and other permanent binders to wet both the surface of the substrate and the functional material inside the ink. Any glass constituents of the substrate will be softened and fused with the glass frit in the ink. As the ink is heated between 700° C. and 850° C., the functional particles in the ink are sintered. Sintering interlocks the functional particles with the glass frit and the substrate to form a completed functional component. Additional information can be found in “Hybrid Microcircuit Technology Handbook, 2nd Ed.”, J. L. Licari, L. R. Enlow, Noyes Publications, Westwood N.J., 1998.

Alternatively, functional material can be applied to a substrate after which a pattern is created by removing a negative of the desired pattern by etching or ablation. Standard circuit boards and printed circuit boards are manufactured in this fashion. Such a process is time consuming and requires the waste and disposal of large amounts of material as well as the use of environmentally hazardous chemicals.

Other known methods used to create the described electronic components includes direct gravure offset printing, the micro pen system developed by Ohmcraft, Inc., laser induced forward transfer, and ink-jet technologies.

### SUMMARY OF THE INVENTION

The present invention relates to a process for producing, but not limited to, electronic components using thick-film ink in an ambient (air) environment. The electronic components include conductors and passive devices such as resistors, capacitors, and inductors. In the present invention, a laser patterning and functionalization process is used for fabricating passive thick-film microelectronic devices. The patterning and functionalization steps in this procedure are integrated as a single step.

In a conventional process, after patterning the inks must be fired at high temperatures for functionalization. This functionalization takes place in an inert (nitrogen) environment to prevent oxidation of the copper thick-film ink. The present invention instead uses a laser to both pattern and to functionalize the thick-film inks simultaneously. The process can be applied to all thick-film inks because of the rapidness of the laser firing minimizes the growth of an oxide layer on the conductor being formed. In addition, this process enables the patterning to be made on low temperature substrates such as mylar. Also, the present invention enables smaller feature sizes than those typically provided by conventional methods, such as screen printing.

The described process can be used for the fabrication of complete micro circuits. While silver based thick-film inks can be used, the present invention enables the use of copper based thick-film ink which provides a potential cost savings over the other thick-film ink conductors. The technology can also be used for rapid prototyping and small batch production manufacturing or for large scale mass production.

According to one aspect of the present invention, a method of making an electronic component using thick-film ink and a substrate is provided. The method includes the steps of coating the substrate with the thick-film ink, sintering the thick-film ink with a laser to provide a patterned thick-film ink, and removing the unsintered thick-film ink from the substrate to reveal the electronic component.

According to another aspect of the present invention there is provided an electronic component including a substrate and a thick-film ink coupled to the substrate, the thick-film ink being sintered and fused to the substrate by the application of laser energy.

### BRIEF DESCRIPTION OF THE DRAWINGS

FIG. 1 illustrates a schematic view of an apparatus for laser fabrication electronic components according to the present invention.

FIGS. 2A and 2B illustrate a flowchart including steps for forming electronic components according to the present invention.

FIGS. 3A to 3F illustrate a method for forming a parallel capacitor according to the present invention as well as a resulting parallel plate capacitor.

FIG. 4 illustrates a graph of the temperatures generated by laser sintering in an ink and a substrate as a function of depth from the surface of the ink.

FIG. 5 illustrates a graph of temperatures generated by laser sintering in an ink and a substrate for three different thermal profiles as a function of depth from the surface of the ink.

FIGS. 6, 7 and 8 illustrate a thermal profile within the substrate from a top view, a side view, and a front view with the application of the laser.

### DETAILED DESCRIPTION OF THE DRAWINGS

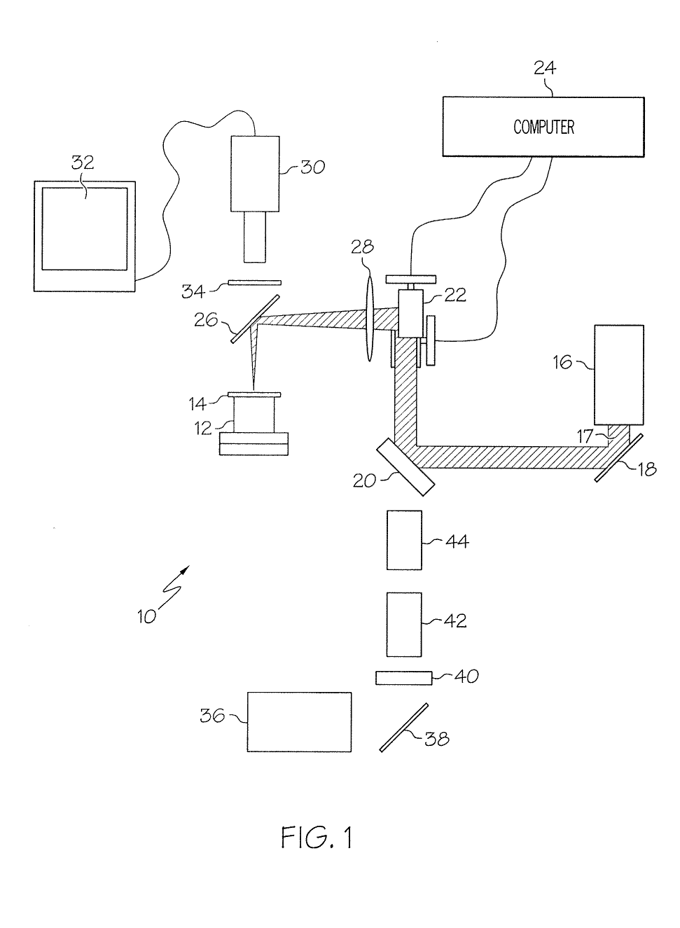

FIG. 1 illustrates an apparatus for laser functionalization and patterning of thick-film inks. In addition, the apparatus of FIG. 1 produces passive microelectronic devices by using laser patterning and functionalization. A fabrication apparatus 10 includes a stage or supporting structure 12 upon which a substrate 14 is patterned. The substrate 14 is patterned after the application of a thick-film ink, to be described in more detail herein, by a fiber laser 16, such as a JDS Uniphase IFL9 fiber laser producing a wavelength of 1.10 micrometers. Other types of laser can also be used, as long as there is sufficient absorption of laser light by the ink. A beam 17 of the fiber laser 16 is redirected by a mirror 18 to a flip mirror 20 which redirects the beam to an X-Y scanner 22. The X-Y scanner 22, under the control of a computer 24, controls the movement of the beam 17 which is directed to a hot mirror 26. The hot mirror 26 redirects the beam toward the substrate 14 where the thick-film inks are patterned. The beam is focused by a lens 28 which is placed between the X-Y scanner 22 and the hot mirror 26. The beam is focused to a predetermined spot size, such as 20 micrometers, at the substrate 14 including the thick-film ink. The process requires less than 0.5 W of power at the substrate for this spot size. A CCD camera 30 is positioned above the substrate 14 to provide an image of the process to a video or TV monitor 32 coupled thereto. Disposed between the CCD camera 30 and the hot mirror 24, is an infrared filter 34 to filter out the infrared of the beam being generated by the fiber laser 16.

As also illustrated in FIG. 1, a neodymium: yttrium lithium fluoride (Nd:YLF) laser 36 generates a second laser beam which can be used to trim the fabricated passive thick-film microelectronic components or devices formed by the laser patterning and functionalization. The beam of the laser 36 is directed to a mirror 38 which redirects the beam through a polarizer 40 and a first and second beam expander 42 and 44. During the patterning performed by the laser 36, the flip mirror 20 is repositioned to enable the laser beam from laser 36 to be directed by the X-Y scanner 22. It is within the scope of the present invention to manipulate the substrate with respect to a fixed laser beam, for instance by using computer numerical control (CNC) of a movable stage 12. The laser 36 is used to trim or adjust the component values of those components which have been created by the fiber laser 16. Laser trimming is a known method of adjusting final values of electronic components on a substrate. Consequently, known methods can be used for laser trimming. It is also within the scope of the present invention, however, to use the fiber laser 16 for adjusting the final values of the components formed on the substrate 14 because the electrical properties of the components will be a function of the thermal profile that they are fired at. In addition, the pulsed laser can be used in laser machining of micro structures which can be formed in the substrate 14, such as grooves, via holes.

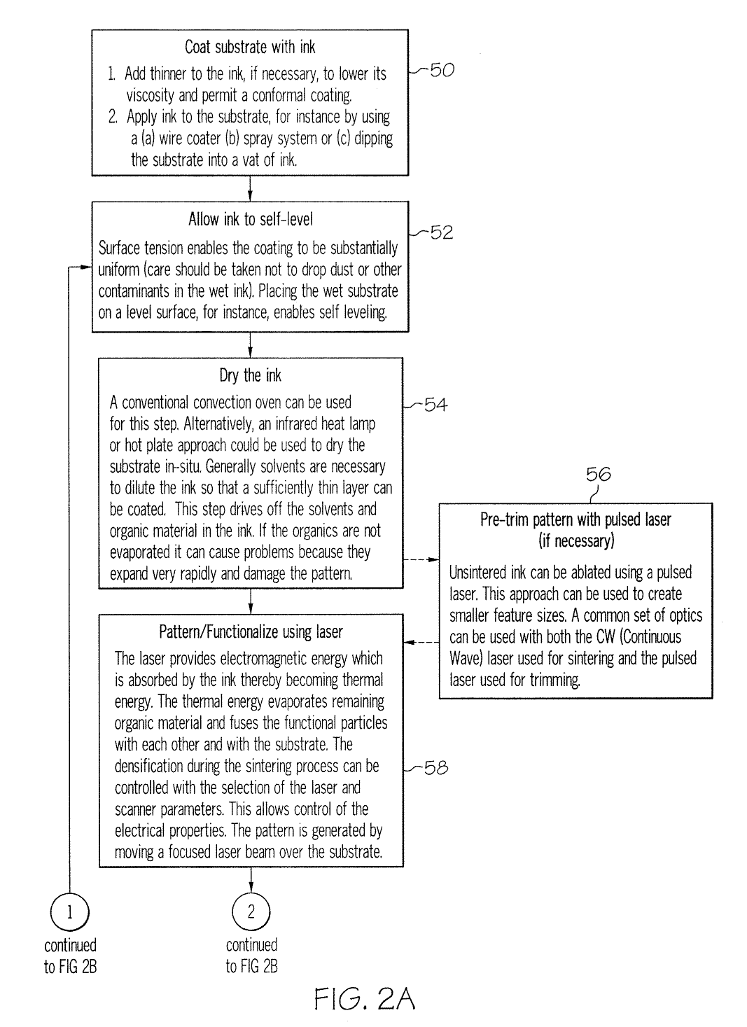

FIGS. 2A and 2B illustrate a process for creating the electronic components of the present invention with the apparatus of FIG. 1. It has been determined that a wide variety of thick-film inks can be patterned and functionalized with the present invention. Thick-film inks available from Dupont which can be used include QS 300 and QM 22, both of which are used to form conductors and which are comprised of silver and platinum. Also, a Dupont ink QM 44 can be used to form dielectric materials. The Dupont ink 6004 is a nitrogen fireable copper ink which has application to the present invention. In addition to the inks from Dupont, Huraeus also provides thick-film inks such as C8772 a low temperature silver ink, SG-480 a sealing glass ink, and C7257, a nitrogen fireable copper ink. Huraeus IP 9333 a high dielectric constant thick-film ink may also be used. Gold conductive inks as well as miscellaneous resistor inks can be used. Any ceramic-metal thick-film ink as well as ferroelectric thick-film inks can also be used. As long as the properties of the thick-film inks are understood, laser parameters including power and time of application, which can be controlled by the X-Y scanner 22, can be adjusted to optimize the use of the thick-film inks.

As illustrated in FIGS. 2A and 2B, the first step in the process is to coat the substrate 14 with a selected ink as illustrated at step 50. Because readily available thick-film inks are being used, a thinner is added to the ink to lower viscosity and to permit a conformal coating. The ink is applied to the substrate 14 using either a wire coater, a spray system, or by dipping the substrate into a vat of ink. Other methods of application are within the scope of the present invention. It is preferred that the ink and its viscosity are selected to enable the application of a consistent thin coat of ink to coat substantially all of the substrate or at least the portion of the substrate which is to be patterned. After the application of the ink to the substrate at step 50, at step 52 the ink is allowed to self-level. Self-leveling enables the surface tension of the applied ink to form a substantially uniform thickness. Self-leveling may be accomplished by placing the wet substrate on a level surface.

After the ink has been allowed to self-level, the ink is dried. A simple conventional convection oven can be used for this process. Alternatively, an infrared heat lamp or a hot plate could be used to dry the substrate in-situ. Because solvents are typically used to dilute the ink so that a sufficiently thin layer can be coated on the substrate, the drying step dries off the solvents and organic material in the ink. The organics should be evaporated to avoid problems which can occur when organics expand rapidly and damage the pattern under heat applied by the laser.

After step 54, an optional step 56 can be performed by ablating the unsintered ink with a pulsed laser, such as the laser 36. This approach can be used to create smaller feature sizes of the various components and conductive paths. A common set of optics can be used with both the continuous wave (CW) laser used for sintering and the pulsed laser used for trimming.

After step 54 or after step 56, if optional step 56 has been performed, the patterning and functionalization of the thick-film ink is made using the laser 16 at step 58. The laser provides electromagnetic energy which is absorbed by the ink which becomes thermal energy. The thermal energy evaporates the remaining organic material and fuses the functional particles with each other and with the substrate. The densification during the sintering process can be controlled with the selection of the laser and scanner 22 parameters. The pattern is generated by moving the focused laser beam over the substrate along a predetermined path with the use of the X-Y scanner 22. It is also within the scope of the present invention to use a larger laser beam which is directed through a mask placed over the substrate which includes the thin-film ink as in a lithographic technique. This could also be accomplished using a spatial light modulator such as by reflecting the beam off a Digital Micromirror Device (DMD). Since the patterning and functionalization of the present invention is a single step process using a laser, the thick-film ink which has now bonded with the substrate at the locations where patterned by the laser remains fixed to the substrate.

The remaining unsintered material is then removed at step 60 to reveal the electronic component. The unsintered ink can be removed with the application of a cleaner or solvent, including methonal. For instance, the unsintered material can be removed by submersing the substrate in a methanol bath inside an ultrasonic cleaner. Ideally, the unsintered ink should be recovered for later use or for proper disposal. After step 60 has been completed, an optional step 62 can be performed. Small features can originally be sintered with a minimum amount of power directed by the laser beam to bond the ink to the substrate. This limits lateral heat diffusion and helps minimize the feature life and size. After the ink adjacent to the pattern is removed, the remaining ink can be lasered again with higher power to increase the densification and electrical performance. This step, while not necessary, can be used where appropriate. After step 60, or optional step 62, has been completed, the substrate, which now includes the patterned devices and/or conductive paths, may be recoated with additional layers of ink if necessary. Additional layers of ink can provide thicker patterns to be built up for sintering of other devices such as conductors for DC/low frequency applications which require a larger skin depth. It is also used for devices with more than one type of element such as circuits having conductors, resistors and dielectrics. Parallel plate capacitors can be formed by this method as described later. Once the component has been completed, the device is fully functional after the final layer of unsintered material is removed as described at step 60.

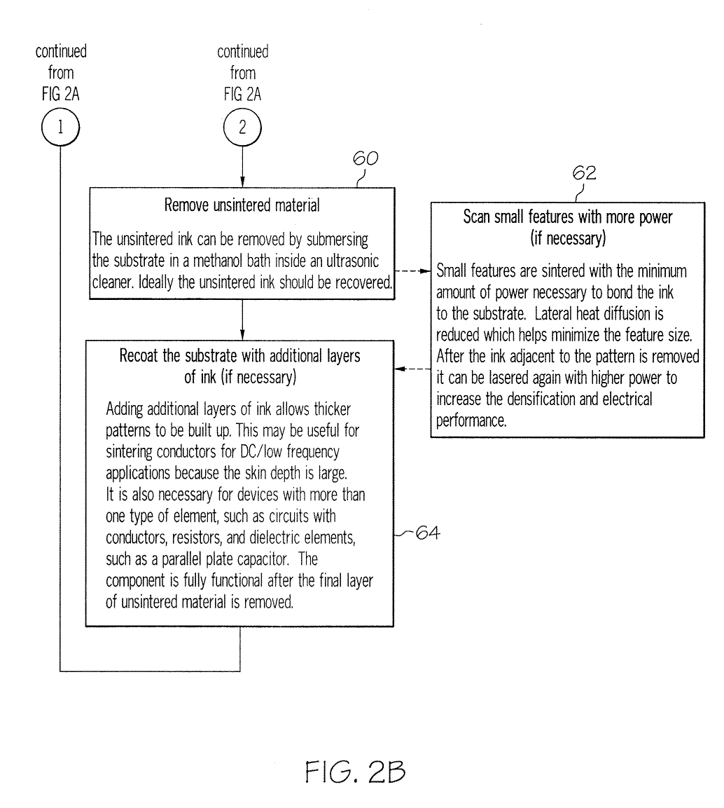

FIGS. 3A to 3F illustrate a method for creating a parallel plate capacitor according to the present invention. FIG. 3A illustrates the substrate after the laser has sintered a bottom or first conductor according to the previously described process. As can be seen, the outline of the capacitor and its first plate 70 are illustrated. The material outside the capacitor plate 70, which is illustrated as material 72, has been removed or cleaned from the substrate in FIG. 3B. In FIG. 3C, a dielectric thin-film ink is placed on top of the conductor 70, previously formed, as well as the rest of the substrate. Then the dielectric material is sintered according to the described process. In FIG. 3D, the unsintered dielectric ink is removed such that the first plate 70 is covered by a dielectric plate 74. In FIG. 3E, the top conductor 76 or second conductive plate 76 is patterned by laser sintering. The remaining unsintered ink is removed in FIG. 3F such that a capacitor has been formed which includes a first plate 70, a second plate 74 and a layer of dielectric material 74 disposed therebetween.

While the present invention includes the laser sintering of thick-film inks, the patterning and functionalization of copper conductors using a copper thick-film ink can be patterned by the present invention in an ambient environment. This patterning and functionalization of copper conductors in an ambient environment does not require firing in nitrogen environments to prevent oxidation. In addition, since a nitrogen environment is not required, other thick-film components such as resistors and dielectrics can be formed using conventional inks. Because the heating cycle is so brief during laser patterning and functionalization of the present invention, oxidation is minimized. The present invention also provides for the fabrication of complete hybrids, for instance, multi-component circuits, without any masks or specialized tooling. In addition, complete hybrid circuits may be created on flexible substrates as well as three dimensional substrates. For instance, the process can be adapted to form conductors and passive devices on non-planar substrates or surfaces by manipulating the substrate relative to a stationary laser beam. In particular, in one application, the present invention may be used to pattern antenna on the surface of a three dimensional substrate, such as a soldier's helmet. It is also possible to fabricate complete hybrid circuits on a low temperature (conformal) substrate, such as mylar.

Typically, substrates such as Mylar cannot survive the sintering temperatures of the conventional thick-film technology. The present invention, however, enables the use of conventional thick-film ink on such substrates because damage is confined to the region closest to the interface with the ink. While some damage is necessary to provide the fusion bond with the thick-film ink, a majority of the substrate located below the bonding interface remains undisturbed.

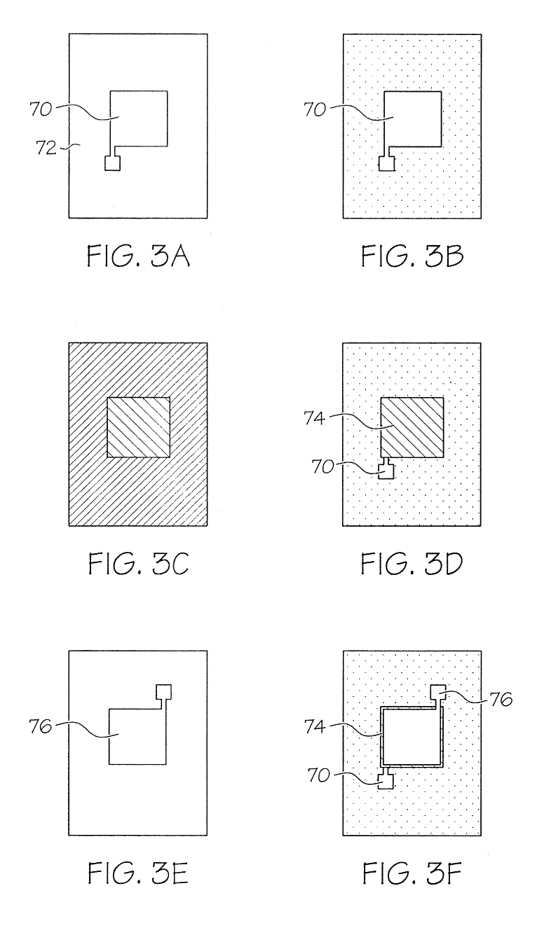

FIG. 4 illustrates a graphical representation of the temperature generated by the laser process as described as a function of a distance from the surface of the ink. The graph includes an X axis 80 indicating the distance and a Y axis 82 indicating temperature. The distance axis 80 illustrates an ink layer 84 having an ink surface 86 placed upon a substrate 88. The ink when deposited on the substrate 88 creates an ink/substrate interface 90. FIG. 4 illustrates that the thermal profile decreases with distance into the substrate and that some of the substrate can be heated above its bulk damage threshold temperature. The duration of this heating, however, is very short on the order of milliseconds. This overheating generates a fusion bond between the ink and the substrate.

As can be seen in FIG. 4, a heating profile 92 which is created by the interaction of the laser with the ink as well as the substrate begins at a point 94. Point 94 illustrates that the temperature at the surface of the ink starts at a certain temperature and drops off at the ink substrate interface 90. At a point 96, a sintering temperature occurs at which a fusion bond between the ink and the substrate is formed. As can be seen, a portion 98 of the substrate 88 is overheated such that the overheating damages this portion of the substrate. As can be seen, a substrate damage threshold temperature occurs at point 100 after which the substrate 88 is not damaged when compared to the portion of the substrate 98 which is overheated.

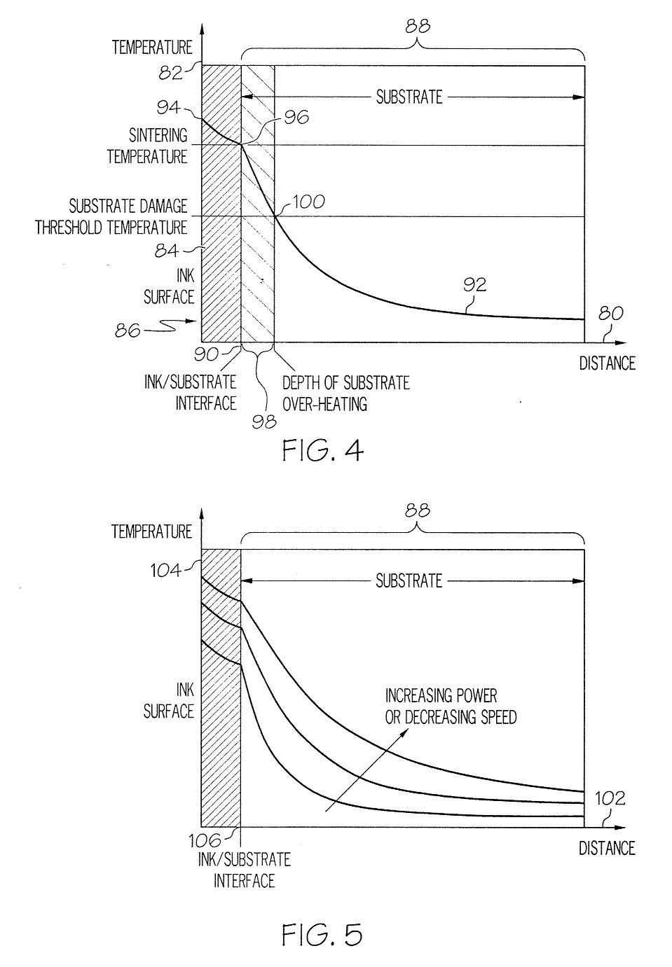

As further illustrated in FIG. 5, a graph including an X axis 102 indicating distance and a Y axis 104 indicating temperature are illustrated. As before, an ink substrate interface 106 is indicated where the ink and substrate meet. In FIG. 5, three thermal profiles are illustrated to indicate that the temperatures of the ink surface and therefore the temperature at the ink substrate interface increase under two conditions. Those conditions include increasing the power of the laser device or decreasing the speed upon which the laser device passes the substrate. While not illustrated in FIG. 5, the depth of substrate overheating becomes greater with increasing power or decreasing speed.

Increasing the power of the laser generates a higher temperature at the surface of the ink and a deeper thermal penetration. Moving the laser more slowly has a similar effect on the maximum temperature because more energy is transferred to the system as the laser dwells over one point for a longer period of time. Depending on the type of ink and the type of substrate, FIG. 5 illustrates that there is an optimum point for which damage to the substrate is minimized. It is important to note that laser sintering heats the entire depth of ink layer but minimizes the damage to the substrate. If there is too little power, there is no bonding between the ink and the substrate and if there is too much power, the substrate is damaged to a point where the sintered device is not usable.

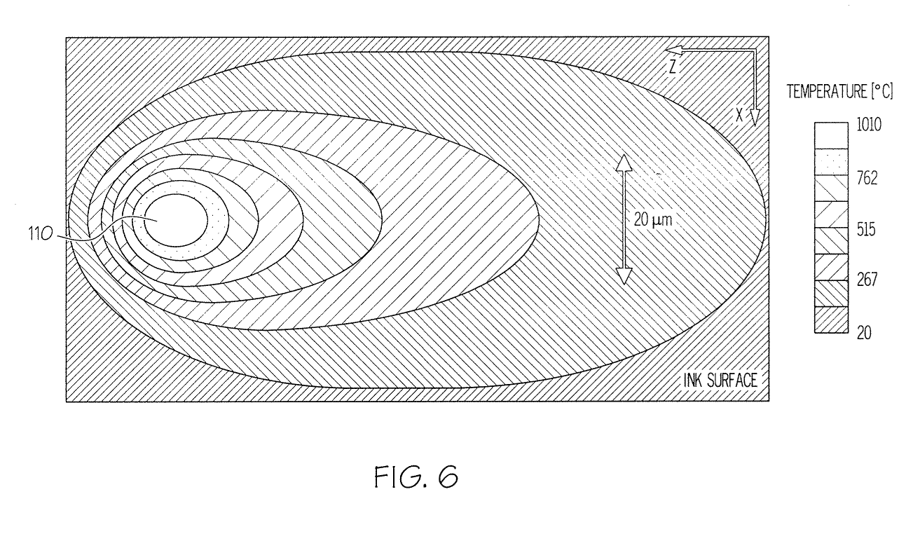

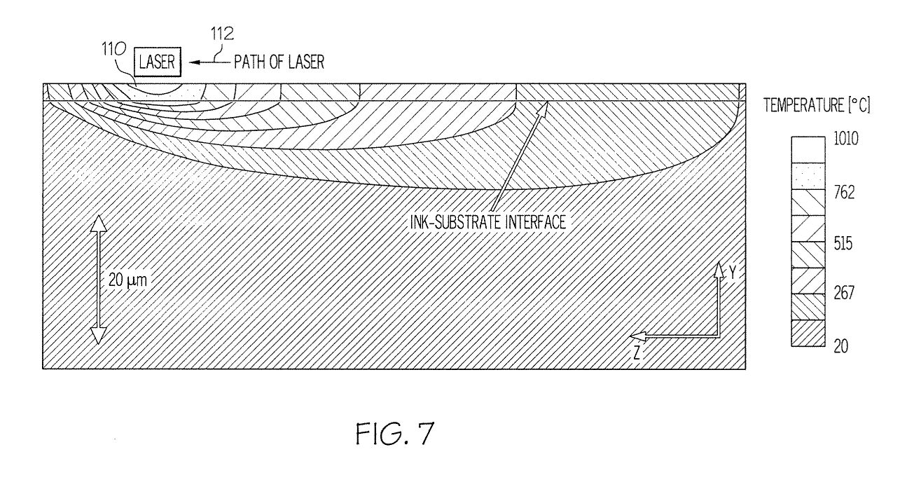

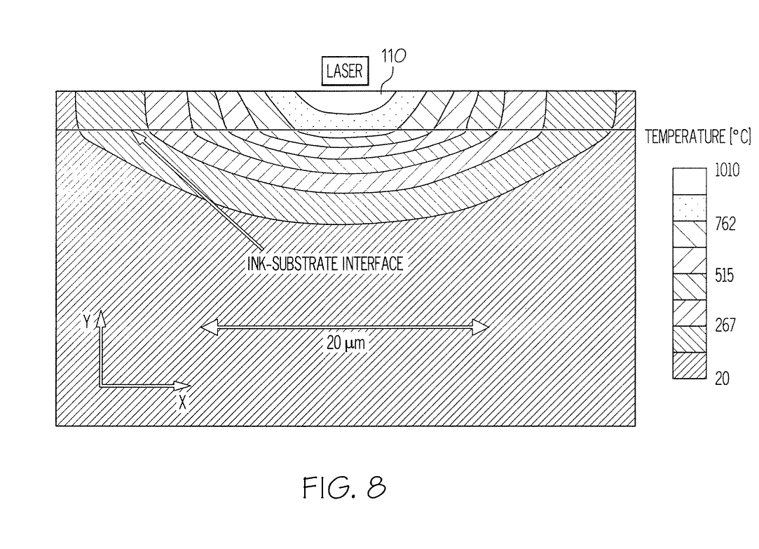

FIGS. 6, 7 and 8 illustrate a thermal profile within the substrate. FIG. 6 illustrates a top down view of the ink surface and the application of the laser beam at a point 110. The laser beam is moving in a direction 112 for FIG. 6 such that the point 110 indicates a temperature of the highest value as illustrated in FIG. 6A. As can be seen in FIG. 6, the areas which extend outwardly from the point 110 drop off in temperature. FIG. 7 illustrates a side view of the substrate where the layer of ink is not illustrated. As in FIG. 6, the central point 110 of the laser has a temperature of the highest value. Moving further into the substrate itself, the temperature drops off as the distance increases from the application point 110 of the laser. FIG. 8 illustrates a front view of the substrate as the laser is moving towards the viewer and out of the page. The central portion 110 again includes the highest temperature whereas temperatures decrease as the distance from the central point 110 increases.

These aspects and additional aspects of the present invention are further described in, for instance, the following documents: (1) Direct Writing of Conventional Thick-film Inks Using MAPLE-DW Process, by Edward C. Kinzel and Xianfan Xu; (2) Selective Laser Sintering of Patch Antennas on FR4, by Hijalti Sigmarsson, Edward Kinzel, William Chappel, and Xianfan Xu; (3) Selective Laser Sintering of Microwave Components, by Edward Kinzel, Hjalti Sigmarsson, Xianfan Xu, and William Chappell; and (4) Heat Transfer in Laser Sintering of Microelectronic Devices, by Edward C. Kinzel, Hjalti H. Sigmarsson, Xianfan Xu, and William J. Chappell each of which is incorporated herein by reference in their entirety.

The present invention uses current materials which are mass produced for conventional thick-film ink industry. It is, however, within the scope of the present invention to use thick-film inks which are specifically developed for the present process. For instance, the thick-film inks used in the present process are thinned to lower the viscosity. This thinning of the thick-film ink need not be done as a separate process should the manufacturer of thick-film ink include the necessary thinner in its production process.

The described process can be used for rapid prototyping of devices that can be produced later using conventional methods. It can also be used for the repair of existing devices.

The described process may also be used to form radio frequency identification (RFID) devices, including RFID tags. It can also be used for the fabrication of chip interconnects, flexible wiring harnesses, integrated sensors such as strain gauges, antennas and microwave components. It can also be used to fabricate the contacts for solar cells and biomedical devices, and sintering energy conversion materials.

Since feature sizes are dependent upon the width of the laser beam, feature sizes below 25 micrometers and even to a few micrometers may be achieved.

While exemplary embodiments incorporating the principals of the present invention have been disclosed above, the present invention is not limited to the disclosed embodiments. Instead this application is intended to convey any variations, uses or adaptations of the invention using its general principals. Further, this application is intended to cover such departures from the present disclosure as come within known or customary practicing the art to which this invention pertains and which falls within the limits of the appended claims.

What is claimed is:

1. A method of making an electronic component using a thick-film ink and a substrate, comprising:
coating the substrate with the thick-film ink;
sintering the thick-film ink with a laser to provide a patterned thick-film ink; and
removing the unsintered thick-film ink from the substrate to reveal the electronic component.

2. The method of claim 1, wherein the removing step includes removing the unsintered thick-film ink from the substrate with a solvent.

3. The method of claim 2, further comprising the step of drying the thick-film ink after the coating step.

4. The method of claim 1, further comprising the step of diluting the thick-film ink before the coating step.

5. The method of claim 1, further comprising the step of leveling the thick-film ink after the coating step.

6. The method of claim 5, wherein the leveling step includes placing the substrate including the thick-film ink on a level surface to enable self-leveling.

7. The method of claim 1, wherein the substrate comprises glass.

8. The method of claim 1, wherein the substrate comprises a flexible material.

9. The method of claim 1, wherein the substrate comprises a three-dimensional surface.

10. The method of claim 1, further comprising the step of applying a laser to the sintered thick-film ink to adjust a value of the electronic component.

11. The method of claim 10, wherein the step of applying a laser to the sintered thick-film ink comprises adjusting the final value of the electronic component.

12. The method of claim 11, wherein the electronic component comprises a resistor.

13. The method of claim 1, further comprising the step of ablating the unsintered thick-film ink with a pulsed laser.

14. The method of claim 1, wherein the sintering step comprises sintering the thick-film ink with a continuous wave laser.

15. The method of claim 13, wherein the sintering step comprises sintering the thick-film ink with a continuous wave laser.

16. The method of claim 15, further comprising the step of ablating unsintered thick-film ink with a pulsed laser to fabricate a component having a feature size smaller than a diameter of the beam of the continuous wave laser.

17. The method of claim 1, wherein the sintering step comprises directing the laser though a mask.

18. The method of claim 1, wherein the sintering step comprises directing the laser to the thick-film ink with a spatial light modulator.

19. The method of claim 18, wherein the spatial light modulator comprises a digital micromirror device.

20. The method of claim 1, where the thick-film ink comprises a material that oxidizes in an air environment at a high temperature.

21. The method of claim 20, wherein the thick-film ink comprises copper.

22. The method of claim 1, wherein the thick-film ink comprises nanoparticles.

23. The method of claim 1, further comprising the step of repeating the coating step, the sintering step, and the removing step to provide a multilayer pattern.

24. The method of claim 23, wherein the multilayer pattern comprises a parallel plate capacitor.

25. The method of claim 23, wherein the multilayer pattern comprises a conductor.

26. The method of claim 1, wherein the method comprises forming an electronic component to repair an existing electronic component.

27. The method of claim 1, further comprising the step of applying at least one of a laser direct writing or laser forward transfer process to lay down a chemical component.

28. The method of claim 1, further comprising the step of applying at least one of a laser direct writing or laser forward transfer process to lay down an organic component.

29. The method of claim 27, wherein the component comprises at least one of a sensing element and a battery.

30. The method of claim 28, wherein the component comprises at least one of a sensing element and a battery.

31. The method of claim 1, wherein the thick-film ink comprises a lowered viscosity to enable coating of the substrate.
